(19) United States
(12) Patent Application Publication
(10) Pub. No.: US 2024/0069453 A1
(43) Pub. Date: Feb. 29, 2024

(54) HEATING ARRANGEMENT AND METHOD FOR HEATING AN OPTICAL ELEMENT

(71) Applicant: Carl Zeiss SMT GmbH, Oberkochen (DE)

(72) Inventors: Susanne Beder, Oberkochen (DE); Matus Kalisky, Oberkochen (DE)

(21) Appl. No.: 18/503,693

(22) Filed: Nov. 7, 2023

Related U.S. Application Data
(63) Continuation of application No. PCT/EP2022/059036, filed on Apr. 5, 2022.

(30) Foreign Application Priority Data
Jun. 17, 2021 (DE) 10 2021 206 203.2

(51) Int. Cl. G03F 7/00; G02B 27/10

(52) U.S. Cl. CPC G03F 7/70891; G02B 27/108

(57) ABSTRACT

A heating arrangement, for example for use in a microlithographic projection exposure apparatus, comprises: at least one beam shaping unit for beam shaping of the electromagnetic radiation steered from a radiation source to the at least one optical element; and a sensor arrangement having at least one intensity sensor. The at least one beam shaping unit comprises at least one microstructured element for steering some the electromagnetic radiation to the sensor arrangement when the heating arrangement is in operation. Methods are provided.

### CROSS-REFERENCE TO RELATED APPLICATIONS

The present application is a continuation of, and claims benefit under 35 USC 120 to, international application PCT/EP2022/059036, filed Apr. 5, 2022, which claims benefit under 35 USC 119 of German Application No 10 2021 206 203.2, filed Jun. 17, 2021. The entire disclosure of each these applications is incorporated by reference herein.

### FIELD

The disclosure relates to a heating arrangement and a method for heating an optical element, such as in a microlithographic projection exposure apparatus.

### BACKGROUND

Microlithography is used for the production of microstructured components, such as for example integrated circuits or LCDs. The microlithography process is carried out in what is known as a projection exposure apparatus, which includes an illumination device and a projection lens. The image of a mask (=reticle) illuminated via the illumination device is in this case projected via the projection lens onto a substrate (e.g., a silicon wafer) coated with a light-sensitive layer (photoresist) and arranged in the image plane of the projection lens, in order to transfer the mask structure to the light-sensitive coating of the substrate.

In projection lenses designed for the EUV range, i.e., at wavelengths of, e.g., approximately 13 nm or approximately 7 nm, mirrors are used as optical components for the imaging process owing to the general lack of availability of suitable light-transmissive refractive materials.

As a result of absorption of the radiation emitted by the EUV light source among other reasons, the EUV mirrors can heat up and can undergo an associated thermal expansion or deformation, which in turn can negatively affect the imaging properties of the optical system. Various approaches are known for addressing surface deformations caused by heat inputs into an EUV mirror.

An exemplary approach includes the use of a heating arrangement on the basis of electromagnetic radiation. With such a heating arrangement, active mirror heating can take place in phases of comparatively low absorption of EUV used radiation, wherein the active mirror heating is correspondingly decreased as the absorption of the EUV used radiation increases. Furthermore, the EUV mirrors can be preheated to the so-called zero crossing temperature prior to the actual operation or prior to having EUV radiation impinge thereon, the coefficient of thermal expansion at the zero crossing temperature having in terms of its temperature dependence a zero crossing, in the neighbourhood of which there is no thermal expansion, or only a negligible thermal expansion, of the mirror substrate material.

It can be a challenge to generate desired heating profiles (which typically should take account of changing radiation intensities, for example on account of the use of illumination settings with an intensity that varies over the optical effective surface of the EUV mirrors, even on a local level) including the provision of the electromagnetic radiation used for heating purposes.

The electromagnetic radiation used for heating purposes is typically guided via optical glass fibres from the respective laser source to the actual optical unit having the individual optical components of the heating arrangement. In addition to the installation space restrictions which have to be considered, an issue can include the susceptibility of the heating arrangement to faults, for example on account of fibres breaking, but also as a consequence of an outage of optical components present within the heating arrangement (e.g., an outage on account of contamination and/or absorption).

A challenge relates to the precise adjustment of the optical system that forms the heating arrangement (for instance with respect to possible decentration and/or tilt in the respective installed position).

Reference is made merely by way of example to DE 10 2017 207 862 A1.

### SUMMARY

The present disclosure seeks to provide a heating arrangement and a method for heating an optical element in an optical system, such as in a microlithographic projection exposure apparatus, which heating arrangement and method can help facilitate an effective avoidance of surface deformations caused by heat inputs into the optical element and optical aberrations accompanying this, while at least partly avoiding undesired issues.

In an aspect, a heating arrangement for heating an optical element with electromagnetic radiation comprises:
at least one beam shaping unit for beam shaping of the electromagnetic radiation steered from a radiation source to the at least one optical element, and
a sensor arrangement having at least one intensity sensor,
wherein the at least one beam shaping unit comprises at least one microstructured element steering some of the electromagnetic radiation to the sensor arrangement when the heating arrangement is in operation.

For example, the radiation source can be a laser source but also a source that emits different radiation or a radiation-emitting object in other embodiments. The electromagnetic radiation steered from the radiation source to the optical element for heating the latter may strike the optical effective surface or else the back side of the optical element. Moreover, the electromagnetic radiation can be infrared radiation or radiation at a different wavelength.

For example, the disclosure can involve the concept of using a beam shaping unit typically present in any case within a heating arrangement (and for example having at least one diffractive or refractive optical element in embodiments) to steer some of the electromagnetic radiation to a sensor arrangement comprising at least one intensity sensor when monitoring the function of the heating arrangement which serves to heat an optical element using electromagnetic radiation, such as in a microlithographic projection exposure apparatus.

Expressed differently, the disclosure can provide for the use of one or more diffractive (or refractive) elements or the like for the purpose of transmitting some of the electromagnetic radiation to one or more predefined positions in angular space, where one or more intensity sensors process the relevant electromagnetic radiation and in each case determine desired information. As a result, the proper function of the heating arrangement can be monitored or ensured at all times during its operation. Moreover, as will still be described in more detail below, the information obtained by way of the sensor arrangement according to the disclosure can also be used for driving or controlling the radiation source (in particular its source power) that generates the electromagnetic radiation. Moreover, the information can likewise be used to measure the position of the optical system that forms the heating arrangement relative to the element to be heated or to adjust the optical system, as likewise still described in more detail below.

The use according to the disclosure of a beam shaping unit, which is present within the heating arrangement and for example in the form of at least one diffractive optical element, for the purposes of output coupling radiation in the direction of a sensor arrangement can provide one or more advantages in this context.

Firstly, as still described below, a plurality of regions of the relevant beam shaping unit or the diffractive optical element, which regions differ from one another, can steer radiation for measurement or monitoring purposes to a single intensity sensor, which can be advantageous in view of the installation space and in view of the number of sensors and cable feeds in terms of costs, and can be advantageous in view of unwanted dynamic influences that occur during operation. In this case, the position of the sensor arrangement can be chosen freely in any way within or else outside of the optical system that forms the heating arrangement, depending on the specific installation space conditions.

Since the beam shaping unit used according to the disclosure for radiation output coupling or the at least one diffractive optical element is a component typically present within the heating arrangement in any case, no additional optical elements are used for the output coupling according to the disclosure of the (measurement) beams that are steered to the sensor arrangement. Moreover, if the beam shaping unit or the diffractive optical element is designed with a plurality of separate regions, these regions can be designed independently of one another both with respect to the intensity of the respective outbound electromagnetic radiation relative to the used light and with respect to the shape of the (measurement) beams.

According to the disclosure, increased outlay both with respect to the embodiment of the beam shaping unit and the at least one diffractive optical element (with respect to the generation of one or more additional measurement beams, and consequently with respect to the increased complexity of the DOE design) is accepted in order, in return, to optionally obtain one or more of the above-described advantages and for example reliable function monitoring.

According to an embodiment, the microstructured element is a diffractive optical element (DOE) or a refractive optical element (ROE).

According to an embodiment, the at least one beam shaping unit has a plurality of separate regions, these separate regions deflecting incident electromagnetic radiation in directions that differ from one another.

According to an embodiment, the sensor arrangement comprises a plurality of intensity sensors.

According to an embodiment, the separate regions of the beam shaping unit deflect electromagnetic radiation to intensity sensors that differ from one another.

According to an embodiment, the heating arrangement comprises a plurality of beam shaping units for impinging on different optical elements, these beam shaping units steering some of the electromagnetic radiation to one and the same sensor arrangement when the heating arrangement is in operation.

According to an embodiment, the heating arrangement comprises a driving unit for driving the radiation source on the basis of signals from the sensor arrangement.

According to an embodiment, the heating arrangement comprises a control unit for controlling the power of the radiation source on the basis of signals from the sensor arrangement.

According to an embodiment, the optical element is a mirror.

According to an embodiment, the optical element is designed for an operating wavelength of less than 30 nm, such as less than 15 nm.

The disclosure further relates to a method for heating an optical element in an optical system, for example using a heating arrangement having the above-described features, wherein electromagnetic radiation from a radiation source impinges on an optical element via at least one beam shaping unit comprising at least one microstructured element, wherein some of the electromagnetic radiation is steered by the at least one microstructured element to a sensor arrangement comprising at least one intensity sensor and the intensity of this portion of the electromagnetic radiation is detected by the sensor arrangement.

According to an embodiment, the power of the radiation source is controlled on the basis of signals from the sensor arrangement.

According to an embodiment, the utilized heating arrangement is adjusted on the basis of signals from the sensor arrangement.

According to an embodiment, the optical element is heated in such a way that a spatial and/or temporal variation of a temperature distribution in the optical element is reduced.

With regard to aspects and further preferred embodiments of the method, reference is made to the above explanations in association with the heating arrangement according to the disclosure.

Further, the disclosure also relates to an optical system, such as in a microlithographic projection exposure apparatus, having at least one optical element and a heating arrangement for heating this optical element, the heating arrangement being embodied with the above-described features.

Further configurations of the disclosure can be gathered from the description and the claims.

The disclosure is explained in greater detail below on the basis of exemplary embodiments illustrated in the accompanying figures.

### BRIEF DESCRIPTION OF THE DRAWINGS

FIGS. 1-5 show schematic representations for explaining basic possible embodiments of a heating arrangement according to the disclosure;

FIGS. 6A-6E show schematic representations for explaining structure and functionality of a specific design of a heating arrangement in an embodiment of the disclosure;

FIG. 7 shows a schematic representation for explaining structure and functionality of a specific design of a heating arrangement in a further embodiment of the disclosure;

FIGS. 8A-8D show schematic representations for explaining a further design and application of a heating arrangement according to the disclosure; and

FIG. 9 shows a schematic representation of the possible structure of a microlithographic projection exposure apparatus designed for operation in the EUV.

### DETAILED DESCRIPTION

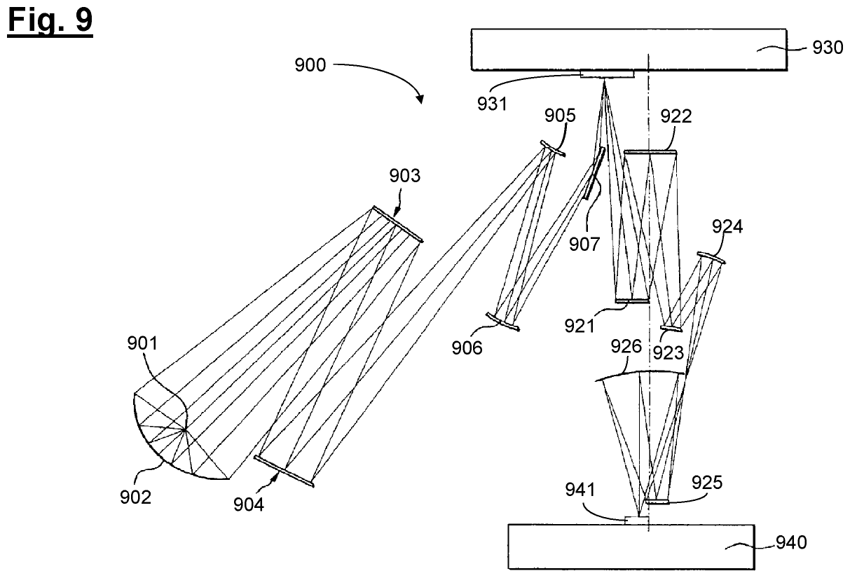

FIG. 9 firstly shows a schematic representation of a projection exposure apparatus 900 which is designed for operation in the EUV and in which the disclosure is able to be realized in an exemplary manner.

According to FIG. 9, an illumination device of the projection exposure apparatus 900 comprises a field facet mirror 903 and a pupil facet mirror 904. The light from a light source unit comprising an EUV light source (plasma light source) 901 and a collector mirror 902 in the example is directed onto the field facet mirror 903. A first telescope mirror 905 and a second telescope mirror 906 are arranged in the light path downstream of the pupil facet mirror 904. A deflection mirror 907 is arranged downstream in the light path, the deflection mirror steering the radiation that is incident thereon at an object field in the object plane of a projection lens comprising six mirrors 921-926. At the location of the object field, a reflective structure-bearing mask 931 is arranged on a mask stage 930, the mask being imaged with the aid of the projection lens into an image plane in which a substrate 941 coated with a light-sensitive layer (photoresist) is situated on a wafer stage 940.

During operation of the optical system or microlithographic projection exposure apparatus, the electromagnetic radiation incident on the optical effective surface of the mirrors is partly absorbed and, as explained in the introduction, results in heating and an associated thermal expansion or deformation, which can in turn result in an impairment of the imaging properties of the optical system. The heating arrangement according to the disclosure or method for heating an optical element can be applied for example to any desired mirror of the microlithographic projection exposure apparatus of FIG. 9.

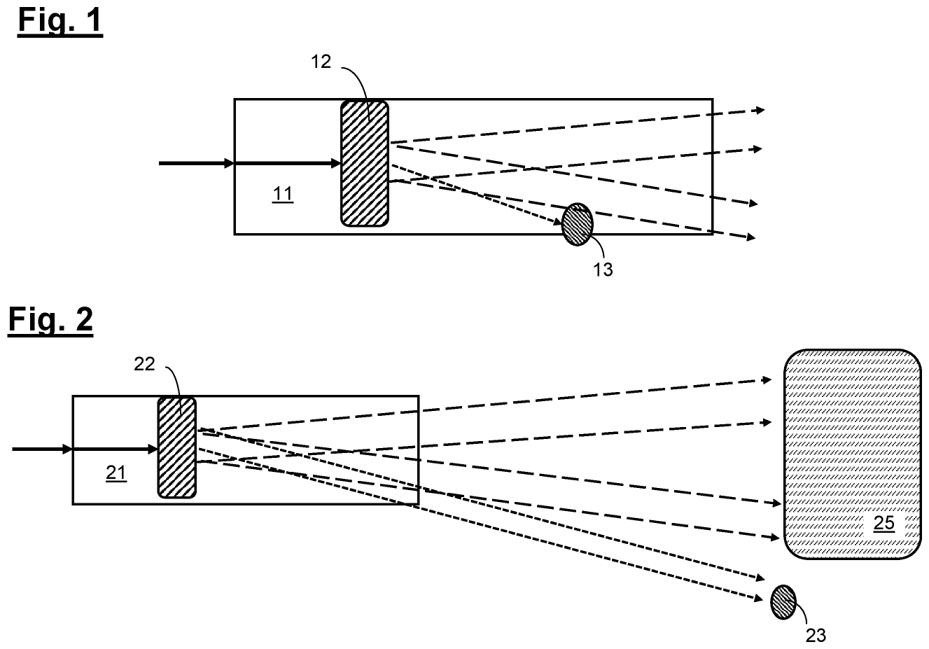

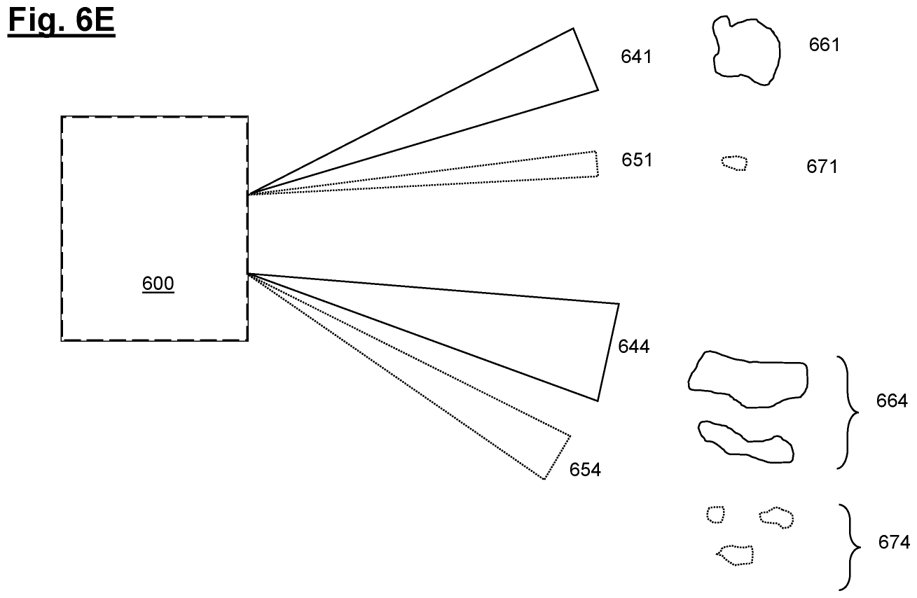

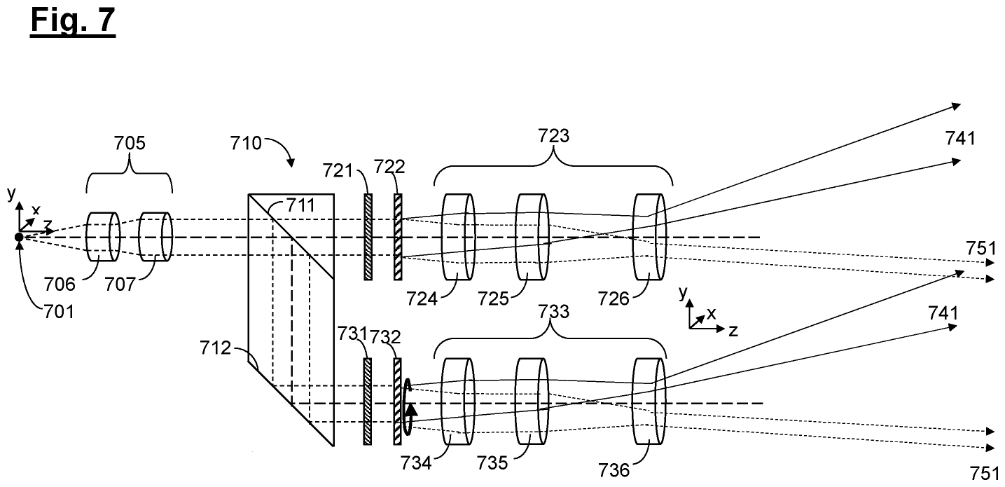

Further, possible designs of a heating arrangement according to the disclosure are initially explained with reference to FIG. 1-5, whereupon specific designs in exemplary embodiments of the disclosure are described on the basis of FIG. 6A-6E and FIG. 7.

What is common to these designs or specific embodiments of a heating arrangement is the use of a beam shaping unit, in particular in the form of at least one diffractive optical element, and the use of this beam shaping unit, inter alia for the purpose of steering some of the electromagnetic radiation to one or more predefined positions in angular space, where then the information for monitoring the function and optionally for further tasks (for instance, driving or controlling the radiation source and/or position monitoring or adjustment) is acquired by way of a sensor arrangement comprising at least one intensity sensor.

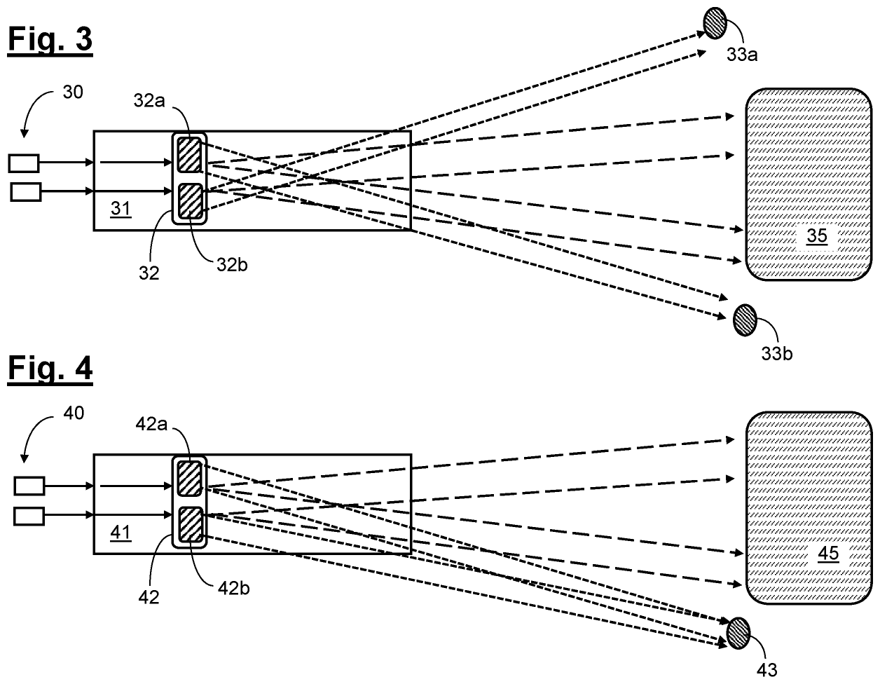

FIG. 1 shows in a schematic and very much simplified representation a beam shaping unit 12 which is situated within an optical system 11 and has the form of a diffractive optical element (DOE) which partially steers electromagnetic radiation entering the optical system 11 that forms the heating arrangement and being incident on the DOE to a sensor arrangement in the form of an intensity sensor 13. The remaining (heating) radiation that is not steered to the intensity sensor 13 emerges from the heating arrangement 11 and serves to impinge on an optical element (not depicted in FIG. 1 but indicated in FIG. 2, for example), for example in the form of an EUV mirror. According to the schematic example of FIG. 1, the intensity sensor 13 that forms the sensor arrangement is situated within the optical system 11.

FIG. 2 likewise shows a further fundamentally possible design in a schematic and much simplified manner, with components that are analogous or substantially functionally identical in comparison with FIG. 1 being designated by reference numerals increased by “10”. In contrast to FIG. 1, the intensity sensor 23 that forms the sensor arrangement is outside of the optical system 21 according to FIG. 2. The optical element to be heated is indicated using “25”.

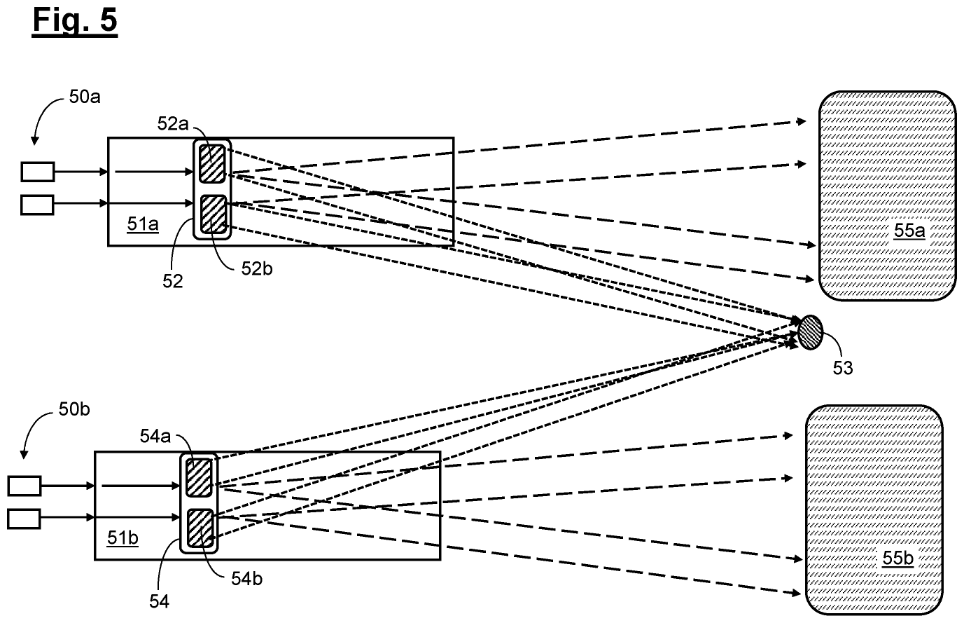

FIG. 3 shows, once again in a schematic and much simplified manner, a further possible basic design, with in contrast to FIG. 2 a DOE that forms the beam shaping unit 32 having two separate regions 32a, 32b, which partly steer electromagnetic (heating) radiation to intensity sensors 33a, 33b that form the sensor arrangement and differ from one another.

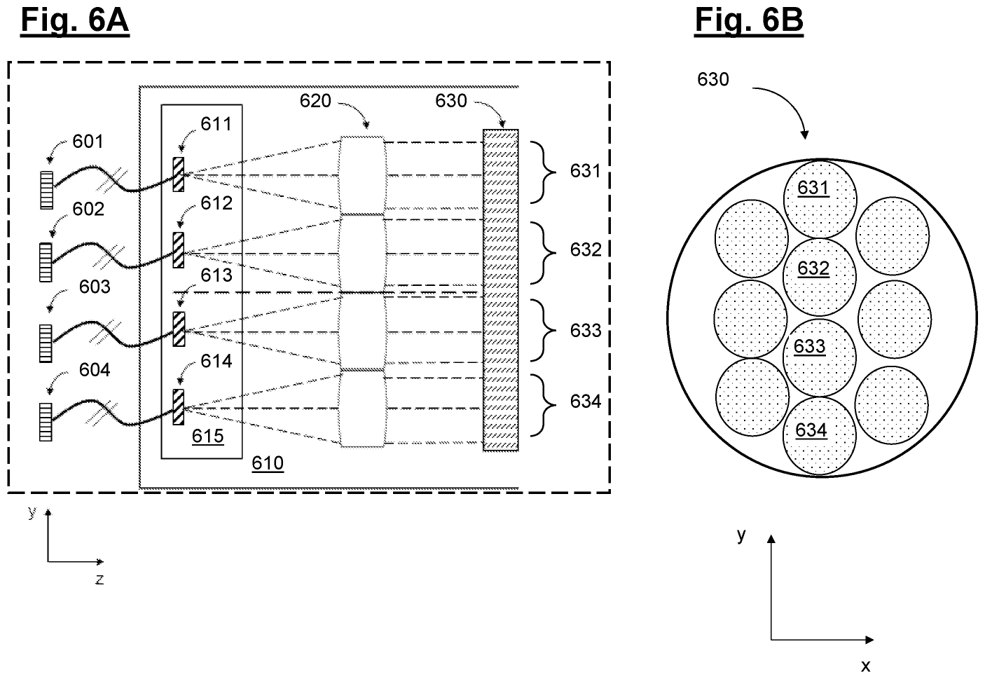

FIG. 4 shows a representation analogous to FIG. 3, with components which are analogous or substantially functionally identical to FIG. 3 being denoted by reference numeral increased by “10”. In contrast to FIG. 3, the separate regions 42a, 42b of the DOE that form the beam shaping unit 42 steer electromagnetic radiation to one and the same intensity sensor 43 according to FIG. 4.

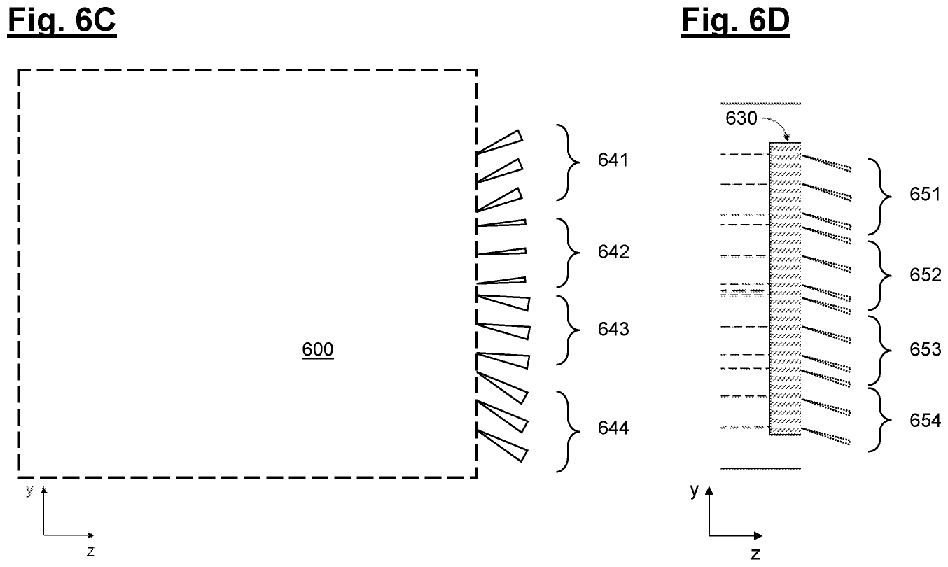

FIG. 5 shows a schematic and much simplified representation for the purposes of explaining a further possible design. According to FIG. 5, the heating arrangement has two separate optical systems 51a, 51b for impinging on separate optical elements 55a, 55b, with each of these optical systems 51a, 51b having a respective design analogous to FIG. 4. In this case, the radiation steered in the direction of the sensor arrangement by the separate regions 52a, 52b and 54a, 54b, respectively, of the DOE forming the respective beam shaping unit 52 or 54 is incident on one and the same intensity sensor 53.

FIG. 6A-6E show schematic representations for explaining structure and functionality of a specific design of a heating arrangement in an embodiment of the disclosure.

According to FIG. 6A, the heating arrangement according to the disclosure comprises in particular a plurality of emitters 601, 602, 603, 604, which may also be present in greater or smaller number. By way of example, the emitters 601, 602, 603, 604 can be designed as IR lasers or IR LEDs (without the disclosure being restricted thereto). According to FIG. 6A, the electromagnetic radiation generated by the emitters 601-604 strikes a beam shaping unit denoted by “630” via a microlens array 620—optionally provided to generate a collimated beam path—and, from the beam shaping unit, the electromagnetic radiation strikes the optical effective surface of an optical element or mirror (not depicted in FIG. 6A).

The beam shaping unit 630 comprises at least one microstructured element, in particular a diffractive optical element (DOE) or refractive optical element (ROE). In embodiments, the beam shaping unit 630 may also have a plurality of beam shaping segments, with each of these beam shaping segments being able to be assigned to a respective emitter 601-604. These beam shaping segments bring about both beam shaping and a beam deflection with respect to the electromagnetic (heating) radiation that is to be steered to the optical effective surface of the optical element to be heated.

As indicated in FIG. 6A and FIG. 6B, the DOE that forms the beam shaping unit 630 has separate regions 631, 632, 633, 634, . . . that are spatially separated from one another. According to FIG. 6C, each of the separate regions generates a first defined angle distribution 641, 642, 643 or 644 of the electromagnetic radiation in angular space, with the angle distributions being able to differ from one another for the separate regions. Moreover, according to FIG. 6D, each of the separate regions respectively generates a second defined angle distribution 651, 652, 653 or 654 of the electromagnetic radiation in angular space, with these second angle distributions also being able to differ from one another for the separate regions. The aforementioned first and second angle distributions may irradiate corresponding or else separated regions in real space, with these regions fundamentally being able to be of any desired form according to FIG. 6E (where regions 661, 671, 664 and 674 are sketched out in exemplary fashion) and also being able to overlap one another.

FIG. 7 shows a schematic representation for explaining structure and functionality of a specific design of a heating arrangement in a further embodiment of the disclosure.

According to FIG. 7, a beam generated by a radiation source (not depicted), which can be purely in exemplary fashion a fibre laser for generating IR radiation at a wavelength of for example 1070 nm, emerges at a fibre end designated by “701” and firstly passes through an optical collimator 705, which according to FIG. 7 is constructed purely in exemplary fashion from lenses 706, 707. The collimated beam emerging from the collimator 705 enters an optical component 710. In embodiments, the fibre end 701 may be adjustable both laterally (i.e., within the xy-plane in relation to the coordinate system plotted in the region of the fibre end 701) and axially (i.e., in the z-direction in relation to this coordinate system) in this case.

A function of the optical component 710 (which comprises a beam splitter 711 and a deflection mirror 712 according to FIG. 7) is to provide two partial beams, each of which is linearly polarized, from the laser beam originally still unpolarized upon entering the component 710, with the linearly polarized partial beams being able to be used for input coupling—optimized with regard to absorption—of heating radiation into the optical element to be heated in each case (e.g., an EUV mirror of the microlithographic projection exposure apparatus from FIG. 9). Such a generation of two partial beams, each of which is linearly polarized, by way of the optical component 710 is advantageous in that a sufficient absorption of the heating radiation can be achieved even when input coupling the generated heating radiation at comparatively large angles of incidence in relation to the respective surface normal (what is known as a “grazing incidence”). Such input coupling of the heating radiation with “grazing incidence” in turn may prove to be desirable in the concrete application situation with respect to structural space aspects if—as is often the case—sufficient structural space is not available within the projection exposure apparatus in the direction perpendicular to the surface of the optical element to be heated. Furthermore, the input coupling of the heating radiation with grazing incidence, depending on the concrete application situation, makes it possible optionally to ensure that the heating arrangement is arranged outside the actual used beam path. Further, input coupling at a grazing incidence makes it possible for the heating radiation to leave the relevant EUV mirror at a correspondingly large angle and not be steered directly to an immediately adjacent mirror. Moreover, the occurrence of reflected IR radiation at the EUV mirror can be reduced in the case of a suitable polarization.

According to FIG. 7, the partial beams each having linear polarization emerge from the optical component 710 along the original light propagation direction along two separate parallel beam paths and each successively pass through an optical retarder 721 and 731, respectively, a diffractive optical element (DOE) 722 and 732, respectively, and an optical telescope 723 and 733, respectively. A suitable setting of the respective polarization direction can be achieved by way of the optical retarders 721 and 731 (which may be designed as lambda/2 plates, for example). The DOEs 722 and 732 serve inter alia as beam shaping units for impressing an individual heating profile into the optical element to be heated by way of beam shaping of the IR radiation to be steered onto the optical effective surface of the optical element. In this case, at least one of the two DOEs 722 and 732 may be arranged in embodiments as to be rotatable about the respective element axis for adjustment purposes, as indicated in exemplary fashion for the element 732. According to FIG. 7, the optical telescopes 723 and 733 are constructed from lenses 724-726 and 734-736, respectively, purely in exemplary fashion. In embodiments, the respective last lens 726 or 736 in the beam path in one of the telescopes 722, 733 or else in both telescopes 722, 733 may be adjustable by way of a lateral displacement (i.e., within the xy-plane in relation to the coordinate system plotted in the region of the lenses 726, 736). The optical telescopes 723 and 733 serve the provision of a suitable additional beam deflection prior to the input coupling of the electromagnetic (heating) radiation into the optical element to be heated or into the EUV mirror.

In the embodiment according to FIG. 7, the DOEs 722 and 732 steer incident electromagnetic (heating) radiation in a manner analogous to the embodiments described above, but in this case in combination with the telescopes 723 and 733 downstream in the optical beam path, to defined positions in angular space, with the corresponding distribution of the radiation in angular and real space brought about by the telescopes 723 and 733 corresponding or else being able to differ from one another. Moreover, each DOE 722 and 732 may have a single region (as depicted in FIG. 7) or else—in this respect analogous to FIG. 6A—a plurality of regions that are separate from one another, with in turn the angle distributions generated by the aforementioned regions for the DOEs 722, 733 corresponding or else being able to be different from one another.

Even though, as described above, the generation according to the design of FIG. 7 of two partial beams which are linearly polarized in each case is advantageous, the optical path (formed by components 712, 731, 732 and 733) used to generate the second partial beam may also be dispensed with in further embodiments. In particular, the light may be unpolarized in this case.

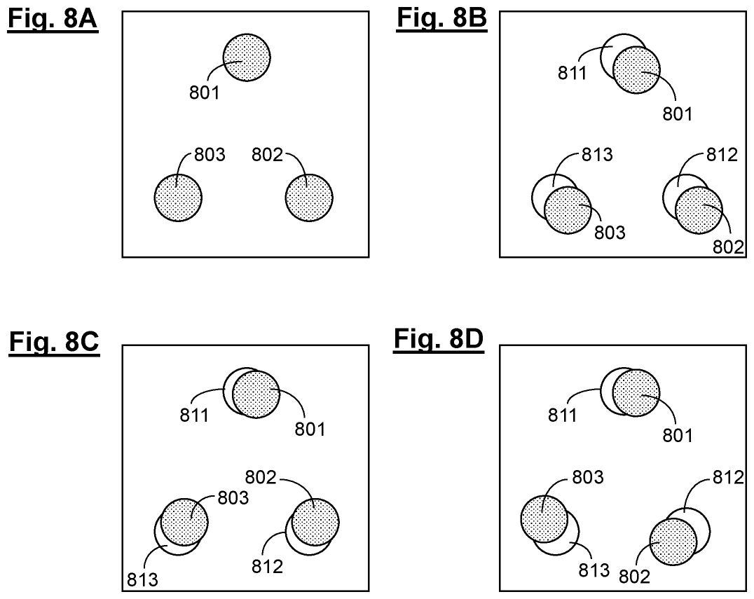

The steering of electromagnetic radiation according to the disclosure to a sensor arrangement via at least one beam shaping unit may, as illustrated on the basis of FIG. 8A-8D, also be used to adjust and control the installed position of the optical system forming the heating arrangement or of the components thereof, it being possible for example to diagnose an (e.g., thermally induced) drift. In FIG. 8A-8D, “801”, “802” and “803” denote light spots generated by the deflection at the location of the sensor arrangement, while “811”, “812” and “813” denote intensity sensors of the sensor arrangement. The intensity sensors 811-813 facilitate a spatially resolved intensity measurement, and so the scenarios schematically indicated in FIG. 8B (corresponding to decentration), FIG. 8C (corresponding to a tilt) and FIG. 8D (corresponding to a twist) are able to be diagnosed. In this case, the sensor arrangement formed by the intensity sensors 811-813 is placed in the direct vicinity of the optical element to be heated or the EUV mirror, in particular also in a region situated outside of the optical element's used region on the optical element itself.

Even though the disclosure has been described on the basis of specific embodiments, numerous variations and alternative embodiments will be apparent to a person skilled in the art, for example through combination and/or exchange of features of individual embodiments. Accordingly, it goes without saying for a person skilled in the art that such variations and alternative embodiments are concomitantly encompassed by the present disclosure, and the scope of the disclosure is restricted only within the meaning of the appended patent claims and the equivalents thereof.

What is claimed is:

1. A heating arrangement, comprising:
a beam shaping unit configured to shape a beam of electromagnetic radiation travelling from a radiation source to an optical element; and
an intensity sensor,
wherein the beam shaping unit comprises a microstructured element configured to steer some of the electromagnetic radiation to the intensity sensor.

2. The heating arrangement of claim 1, wherein the microstructured element comprises a diffractive optical element.

3. The heating arrangement of claim 1, wherein the microstructured element comprises a refractive optical element.

4. The heating arrangement of claim 1, wherein the beam shaping unit comprises a plurality of separate regions configured to incident electromagnetic radiation in directions that differ from one another.

5. The heating arrangement of claim 4, wherein the heating arrangement comprises a plurality of intensity sensors.

6. The heating arrangement of claim 5, wherein the separate regions of the beam shaping unit deflect electromagnetic radiation to intensity sensors that differ from one another.

7. The heating arrangement of claim 1, wherein the heating arrangement comprises a plurality of intensity sensors.

8. The heating arrangement of claim 1, further comprising a further beam shaping units configured to shape a beam of the electromagnetic radiation travelling from the radiation source to a further optical element.

9. The heating arrangement of claim 1, further comprising a driving unit configured to drive the radiation source based information from the intensity sensor.

10. The heating arrangement of claim 9, further comprising a control unit configured to control a power of the radiation source based on information from the intensity sensor.

11. The heating arrangement of claim 1, further comprising a control unit configured to control a power of the radiation source based on information from the intensity sensor.

12. The heating arrangement of claim 1, wherein the optical element comprises a mirror.

13. The heating arrangement of claim 1, wherein the electromagnetic radiation has a wavelength of less than 30 nm.

14. An optical system, comprising:
an optical element; and
a heating arrangement, comprising:
a beam shaping unit configured to shape a beam of electromagnetic radiation travelling from a radiation source to the optical element; and
an intensity sensor,
wherein the beam shaping unit comprises a microstructured element configured to steer some of the electromagnetic radiation to the intensity sensor.

15. The optical system of claim 14, wherein the optical system is a microlithographic projection exposure apparatus.

16. The optical system of claim 15, wherein the electromagnetic radiation has a wavelength of less than 30 nm.

17. A method, comprising:
using a beam shaping unit to direct a first portion of electromagnetic radiation to an optical element, the beam shaping unit comprising a microstructured element; and
using the microstructured element to direct a second portion of the electromagnetic radiation to an intensity sensor.

18. The method of claim 17, further comprising controlling a power of the radiation source based on information from the intensity sensor.

19. The method of claim 17, further comprising adjusting the method based on information from the intensity sensor.

20. The method of claim 17, comprising heating the optical element to reduce a spatial and/or temporal variation of a temperature distribution in the optical element.
